(19) United States
(12) Patent Application Publication
(10) Pub. No.: US 2008/0169435 A1
(43) Pub. Date: Jul. 17, 2008

(54) Ion beam monitoring arrangement

(75) Inventors: Takao Sakase, Rowley, MA (US); Marvin Farley, Ipswich, MA (US); Steven C. Hays, Rowley, MA (US)

Correspondence Address: APPLIED MATERIALS, INC., P. O. BOX 450A, SANTA CLARA, CA, 95052, US

(73) Assignee: APPLIED MATERIALS, INC.

(21) Appl. No.: 11/652,651

(22) Filed: Jan. 12, 2007

(51) Int. Cl. G21K 5/10; G01R 31/00; G06F 9/30

(52) U.S. Cl. 250/492.21; 324/72

(57) ABSTRACT

This invention relates to an ion beam monitoring arrangement for use in an ion implanter where it is desirable to monitor the floating potential across an ion beam used for implantation. The invention provides a ion beam monitoring arrangement comprising a device configured to measure the floating potential of an ion beam when incident thereon, wherein the device is coupled to a substrate support so as to face outwardly in a position so as not to be obscured by a substrate of the contemplated size when held by the substrate holder. Thus, measurements of the floating potential may be taken with a substrate held in place. The ion beam monitoring arrangement may be used to move the device into the ion beam in much the same way as it used to scan a substrate through the ion beam.

### FIELD OF THE INVENTION

This invention relates to an ion beam monitoring arrangement for use in an ion implanter where it is desirable to monitor the floating potential across an ion beam used for implantation. This invention also relates to an ion implanter including such a ion beam monitoring arrangement, and to methods of measuring the floating potential of an ion beam and of implanting a substrate.

In particular, the present invention relates to measuring the floating potential in and around an ion beam at or close to the plane of a substrate being implanted so as to be able to control the ion beam to minimise charge accumulation caused by the ion beam. This may be performed through ion beam tuning and/or a plasma flood system.

### BACKGROUND OF THE INVENTION

Ion implanters are well known and generally conform to a common design as follows. An ion source produces a mixed beam of ions from a precursor gas or the like. Only ions of a particular species are usually required for implantation in a substrate, for example a particular dopant for implantation in a semiconductor wafer. The required ions are selected from the mixed ion beam using a mass-analysing magnet in association with a mass-resolving slit. Hence, an ion beam containing almost exclusively the required ion species emerges from the mass-resolving slit to be transported to a process chamber where the a substrate is held in place by a substrate holder. Often the ion beam size is smaller than the substrate to be implanted. In order to ensure ion implantation across the whole of the substrate, the ion beam and substrate are moved relative to one another such that the ion beam scans the entire substrate surface. This may be achieved by (a) deflecting the ion beam to scan across the substrate that is held in a fixed position, (b) mechanically moving the substrate whilst keeping the ion beam path fixed or (c) a combination of deflecting the ion beam and moving the substrate. Generally, relative motion is effected such that the ion beam traces a raster pattern on the substrate.

Our co-pending U.S. patent application Ser. No. 10/119,290 describes an ion implanter of the general design described above. A single substrate is held in a moveable substrate holder. While some steering of the ion beam is possible, the implanter is operated such that ion beam follows a fixed path during implantation. Instead, the substrate holder is moved along two orthogonal axes to cause the ion beam to scan over the substrate following a raster pattern.

Ion beams often have a residual positive charge that is detrimental for at least two reasons. First, it causes space-charge blow-up of the ion beam, particularly at the substrate where the ion beam tends to be at its least energetic. Second, the net positive charge in and around the ion beam seen at the plane of the substrate is transferred to the substrate during implantation, and this accumulation of charge can damage devices being fabricated on the substrate. This is a particular problem in mechanically-scanned serial implanters where scan speeds are slow. In order to address the problem of charge accumulation, the ion implanter may be used to tune the ion beam and/or an electron source may be used to introduce neutralising electrons to the ion beam. The electron source may comprise a plasma flood system placed immediately upstream of the substrate.

It is often desirable to measure the floating potential in and around an ion beam in order to improve control of the implantation process. For example, the floating potential of the ion beam is a measure of the net positive charge carried by the ion beam. As such, a measurement of the floating potential can be used to control beam tuning and operation of the plasma flood system (or other electron source) to improve ion beam neutrality. For example, where the measurement indicates that the net positive charge of the ion beam is unacceptably high, the plasma flood system may be adjusted to produce more electrons.

WO02/23583 describes a system for taking measurements of the floating potential of an ion beam at the wafer plane. A test wafer is provided that may be loaded onto a wafer holder and held in the ion beam. The test wafer comprises an array of sensors formed on its surface. The sensors essentially comprise conductive tracks extending from the front face of the test wafer, through the test wafer, to a ring of contacts provided around the periphery of the back face of the test wafer. An interface device connects with the contacts to take the electrical signals to external circuitry used to measure the floating potential of the ion beam. Essentially, the circuitry comprises a high input impedance voltmeter. By measuring the floating potential at each sensor, a map of the floating potentials across the ion beam can be derived.

By the very nature of the test wafer, measurements cannot be made during an implant. In particular, for a measurement to be taken, an implant must stop, a wafer must be unloaded from the wafer holder, the test wafer loaded, the measurements taken, the test wafer unloaded, a new wafer loaded and only then can implanting resume. Clearly, this is a time-consuming process that reduces the throughput of processed wafers through the ion implanter.

### SUMMARY OF THE INVENTION

Against this background, and from a first aspect, the present invention resides in a ion beam monitoring arrangement for an ion implanter, the ion beam monitoring arrangement comprising: a substrate support comprising a support arm and, mounted thereto, a substrate holder for holding a substrate of contemplated size; an actuator arranged to cause relative motion between the substrate holder and the ion beam; and a device configured to measure the floating potential of an ion beam when incident thereon; wherein the device is coupled to the substrate support so as to face outwardly in a position so as not to be obscured by a substrate of the contemplated size when held by the substrate holder.

Of course, the relative motion may correspond to moving the substrate support relative to a fixed ion beam, scanning the ion beam relative to a fixed substrate support, or a mixture of the two. Advantageously, the device is located on the substrate support such that it is not obscured when a substrate is in position on the substrate holder. For example, when used in an ion implanter, the device will still enjoy line of sight with the ion beam, even when a substrate such as a semiconductor wafer is in position on the substrate holder.

As measurements of the floating potential of the ion beam may be taken with a substrate in situ, the present invention removes the need to unload and load the substrate before and after measurements are taken, thus increasing the throughput of the associated machine, be it an ion implanter or any other type of equipment. A further advantage is that measurements may be taken during processing of the substrate. For example, in an ion implanter, measurements may be taken between implanting along scan lines.

The device may be located in a variety of positions on the substrate support, and may be positioned to face a variety of directions. For example, the device may be positioned so as to face in the same direction as a substrate when held by the substrate holder, or in the opposite direction or at 90° to that direction. Possible arrangements include coupling the device to the support arm or to the substrate holder.

Optionally, the device is mounted within the support arm so as to face outwardly through an aperture provided in the support arm. Alternatively, the device may be mounted to the substrate holder, for example on the back face to face away from the substrate or on an edge to face at 90° to the substrate. Where it is desired for the device to face in the same direction as the substrate, the device may be mounted to a part of the substrate holder that extends beyond the extent of a substrate of the contemplated size when held by the substrate holder. This part may be either integral with the substrate holder, or may be attached to the substrate holder. Optionally, the device is mounted within the substrate holder so as to face outwardly through an aperture provided in the substrate holder.

Preferably, the actuator is arranged to drive the support arm thereby causing the substrate holder to move through the ion beam. Associating the device with the a substrate support that effects mechanical scanning of the substrate through the ion beam is convenient as the substrate support may be used to drive the device into a desired position for one or measurements of the floating potential to be taken.

Optionally, the support arm is rotatable about its longitudinal axis. This provides a convenient way of rotating the support arm where the device does not face in the same direction as a substrate held in position on the substrate holder. This may be used, for example, to make the device face an ion beam in an ion implanter.

Preferably, the actuator has a part operable to drive the support arm along its length. Additionally, or alternatively, the actuator may have a part operable to drive the support arm perpendicularly to its length. This provides a convenient mechanism for allowing the device to be moved to different positions in and around the ion beam where measurements of the floating potential in and around the ion beam may be taken.

The device may be integral with the substrate support. Optionally, the device comprises a front, insulating plate with an aperture provided therein. The device may be attached to the substrate support using the insulating plate. The device may comprise a sensor positioned behind the aperture of the insulating plate. In a contemplated embodiment, the sensor is connected electrically to a resistor and a current meter. Alternatively, a non-contacting voltmeter may be used as the device.

Optionally, the device is one of an array of like devices. Using an array of devices means that a profile may be obtained of the floating potential of an ion beam quickly, in that the actuator need only be used to cause relative motion such that the support arm is in a single position relative to the ion beam where the array of sensors cover the ion beam. The ion beam may then be sampled, with each device providing a measurement of the floating potential of the ion beam at its position. Of course, the trade-off against this increased speed is the expense of providing the additional devices, plus the corresponding means for processing the many signals either in parallel or sequentially.

From a second aspect, the present invention resides in an ion implanter comprising one of the ion beam monitoring arrangements described above.

From a third aspect, the present invention resides in a method of measuring the floating potential of an ion beam using an ion implanter including any of the ion beam monitoring arrangements described above, the method comprising: using the actuator to cause relative motion between the support arm and the ion beam such that the device adopts a first measuring position in the ion beam; and using the device to measure the floating potential at the first measuring position. A display may be provided of the floating potential, either graphically or as text.

The actuator may be used such that the device adopts an array of measuring positions in the ion beam, and using the device to measure the floating potential at each measuring position. The floating potentials so measured may be displayed to provide a profile of the floating potential of the ion beam. This is best done graphically, for example using colour coding to represent the magnitude of values. Further computation may be performed to provide continuous data rather than the array of values measured. For example, interpolation may be used to derive a contour plot of floating potentials in the ion beam.

The actuator may be used to cause relative motion such that the ion beam traces any number of paths over the substrate, such as a raster pattern. An infinite variety of the number of data points and their arrangement is possible. It will be obvious that some are more useful than others. For example, regularly spaced arrays of points are useful, as our some non-uniform arrays such as those where a greater density of points exists at and around the centre of the ion beam.

Preferably, the actuator is used to cause the substrate support to move relative to a fixed ion beam.

From a fourth aspect, the present invention resides in a method of implanting a substrate using an ion implanter including any of the ion beam monitoring arrangements described above, the method comprising: generating an ion beam using an ion source of the ion implanter; guiding the ion beam through the ion implanter towards the substrate holder using ion optics of the ion implanter; using the actuator to cause relative motion between a substrate held by the substrate holder and the ion beam to form a first scan line as the ion beam passes over the substrate; repeating the above step of using the actuator so as to cause the ion beam to scan over the substrate repeatedly to form a series of scan lines; and, between two successive steps of using the actuator to form scan lines across the substrate, using the actuator to cause relative motion such that the device adopts a first measuring position in the ion beam and using the device to measure the floating potential at the first measuring position.

Such a method is advantageous as it allows measurements to be made of the floating potential part way through an implant. This allows corrections to be made, e.g. the ion beam may be adjusted or the operation of a plasma flood system may be adjusted to improve ion beam neutrality as measured by the device. Of course, such adjustments may still be made whenever measurements of the floating potential are made, and not just when they are made between scan lines. For example, measurements of the floating potential may be made between multiple passes over the substrate during an implant.

Moreover, there is no need to remove the substrate during measurement of the floating potential; this would be particularly undesirable and extremely difficult to implement where the measurement is taken part way through an implant such that only some of the necessary scan lines had been traced.

Of course, an array of measurements may be taken between scan lines by using the actuator such that the device adopts an array of measuring positions in the ion beam, and using the device to measure the floating potential at each measuring position.

Preferably, the actuator is used to cause the substrate support to move relative to a fixed ion beam.

The present invention also extends to a controller arranged to implement any of the above methods, to a computer programmed to implement any of the above methods, to a computer program that when loaded and executed on a computer, causes that computer to implement any of the above methods, and to a computer readable medium carrying such a computer program.

### BRIEF DESCRIPTION OF THE DRAWINGS

Examples of the invention will now be described with reference to the accompanying drawings, in which:

FIG. 1 is a schematic representation of a conventional ion implanter;

FIG. 2a shows a schematic side view of an ion implanter in which a substrate is mounted on a substrate support;

FIG. 2b shows a part section along line AA of FIG. 1a;

FIG. 3 is a schematic representation of a device for measuring the floating potential of an ion beam according to an embodiment of the present invention;

FIG. 4 is a perspective view of a substrate support comprising the device of FIG. 3 located-on the arm;

FIG. 5 is a perspective view of a substrate support comprising the device of FIG. 3 located on a tab mounted to the edge of the wafer holder;

FIG. 6 is a perspective view of a substrate support comprising the device of FIG. 3 located on the reverse of the wafer holder; and

FIG. 7 is a perspective view of a substrate support comprising the device of FIG. 3 located on the edge of the wafer holder.

### DESCRIPTION OF THE PREFERRED EMBODIMENTS

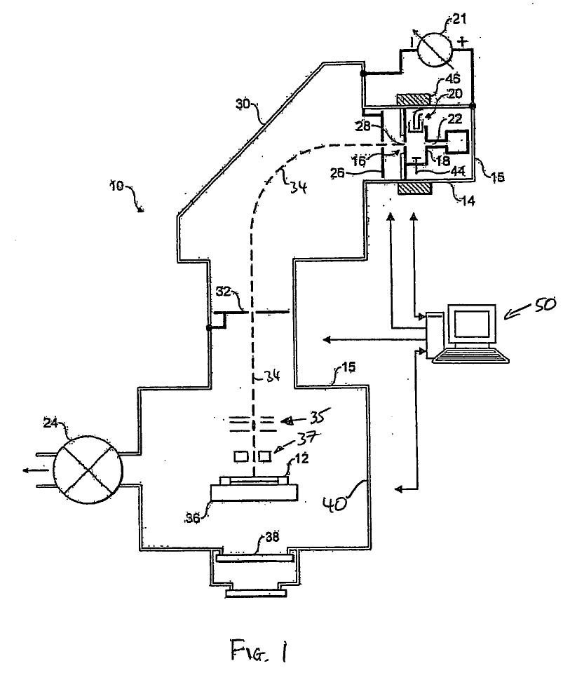

In order to provide a context for the present invention, an exemplary application is shown in FIG. 1, although it will be appreciated that this is merely an example of an application of the present invention and is in no way limiting.

FIG. 1 shows a known ion implanter 10 for implanting ions in semiconductor wafers 12. Ions are generated by the ion source 14 to be extracted and follow an ion path 34 that passes, in this embodiment, through a mass analysis stage 30. Ions of a desired mass are selected to pass through a mass-resolving slit 32 and carry on eventually to strike the semiconductor wafer 12.

The ion implanter 10 contains an ion source 14 for generating an ion beam of a desired species that is located within a vacuum chamber 15 evacuated by pump 24. The ion source 14 generally comprises an arc chamber 16 containing a cathode 20 located at one end thereof. The ion source 14 may be operated such that an anode is provided by the walls 18 of the arc chamber 16. The cathode 20 is heated sufficiently to generate thermal electrons.

Thermal electrons emitted by the cathode 20 are attracted to the anode, the adjacent chamber walls 18 in this case. The thermal electrons ionise gas molecules as they traverse the arc chamber 16, thereby forming a plasma and generating the desired ions.

The path followed by the thermal electrons may be controlled to prevent the electrons merely following the shortest path to the chamber walls 18. A magnet assembly 46 provides a magnetic field extending through the arc chamber 16 such that thermal electrons follow a spiral path along the length of the arc chamber 16 towards a counter-cathode 44 located at the opposite end of the arc chamber 16.

A gas feed 22 fills the arc chamber 16 with the species to be implanted or with a precursor gas species. The arc chamber 16 is held at a reduced pressure within the vacuum chamber 15. The thermal electrons travelling through the arc chamber 16 ionise the gas molecules present in the arc chamber 16 and may also crack molecules. The ions (that may comprise a mixture of ions) created in the plasma will also contain trace amounts of contaminant ions (e.g. generated from the material of the chamber walls 18).

Ions from within the arc chamber 16 are extracted through an exit aperture 28 provided in a front plate of the arc chamber 16 using a negatively-biased (relative to ground) extraction electrode 26. A potential difference is applied between the ion source 14 and the following mass analysis stage 30 by a power supply 21 to accelerate extracted ions, the ion source 14 and mass analysis stage 30 being electrically isolated from each other by an insulator (not shown). This high energy beam of ions is less susceptible to space-charge blow-up.

The mixture of extracted ions are then passed through the mass analysis stage 30 so that they pass around a curved path under the influence of a magnetic field. The radius of curvature traveled by any ion is determined by its mass, charge state and energy, and the magnetic field is controlled so that, for a set beam energy, only those ions with a desired mass to charge ratio and energy exit along a path 34 coincident with the mass-resolving slit 32. The emergent ion beam is then transported to the process chamber 40 where the target is located, i.e. the wafer 12 to be implanted or a beam stop 38 when there is no wafer 12 or wafer holder in the target position. Prior to arriving at the wafer 12, the beam is decelerated using a deceleration lens assembly 35 positioned between the mass analysis stage 30 and the target position.

The ion beam 34 then passes through a plasma flood system 37 located immediately in front of the wafer 12. The plasma flood system 37 operates to introduce electrons into the ion beam 34 therein to neutralise any net positive charge in the ion beam 34, and to ensure the wafer 12 does not charge due to the incident ion beam 34.

Firstly, the ion beam 34 strikes the wafer 12 that is held by a scanning arm assembly 51 (as shown in FIG. 1). The wafer 12 is mounted on a wafer holder 36, wafers 12 being successively transferred to and from the wafer holder 36, for example through a load lock (not shown).

The ion implanter 10 operates under the management of a controller, such as a suitably programmed computer 50, that also receives diagnostic measurements from the ion implanter 10 during its operation. The controller 50 optimises performance of the ion implanter 10 and implements selected implant recipes.

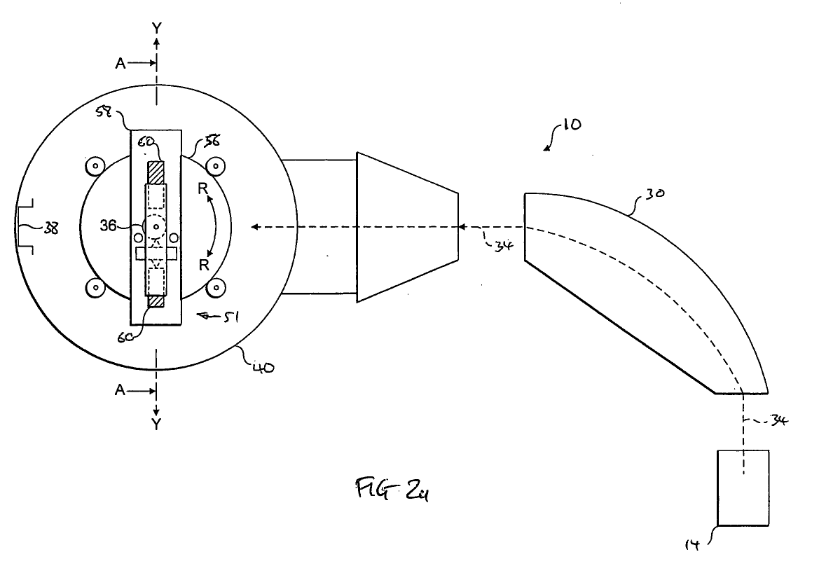

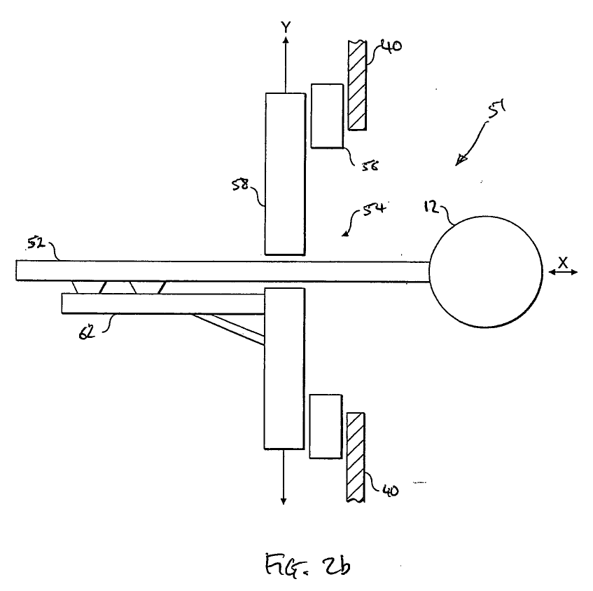

A simplified schematic side view of the ion implanter 10 of FIG. 1 is shown in FIG. 2a and a corresponding part sectional view along the line AA of FIG. 2a is shown in FIG. 2b. The ion implanter 10 includes ion source 14 arranged to generate ion beam 34 that passes through the mass analyser 30. The ions 34 exiting the mass analyser 30 are decelerated (the deceleration lens assembly 35 and the plasma flood system 37 are omitted from FIG. 2a or 2b). The process chamber 40 contains a wafer 12 to be implanted, as may be seen in FIG. 2b, and beam stop 38.

A scanning arm assembly 51 is shown in FIGS. 2a and 2b (explained in more detail below) that is of the type that mechanically scans the wafer 12, although it is to be remembered that the present invention may be used in an ion implanter 10 where the ion beam 34 is scanned relative to a fixed wafer holder 36. The scanning arm assembly 51 of FIGS. 2a and 2b permits movement of the wafer 12 in multiple directions, while the ion beam 34 is maintained along a fixed path relative to the process chamber 40 during implant.

The wafer 12 is mounted electrostatically upon the wafer holder or chuck 36 of the scanning arm assembly 51 that also comprises an elongate support arm 52 to which the chuck 36 is connected. The chuck 36 and support arm 52 together comprise a substrate support. The support arm 52 extends out through the wall of the process chamber 40 in a direction generally perpendicular with the direction of the ion beam 34. The support arm 52 passes through a slot 54 (see FIG. 1b) in a rotor plate 56 which is mounted adjacent to a side wall of the process chamber 40. The end of the support arm 52 is mounted through a sledge 58. The support arm 52 is substantially fixed relative to the sledge 58 in the Y-direction as shown in FIGS. 2a and 2b. The sledge 58 is movable in a reciprocating manner relative to the rotor plate 56 in the direction Y shown in FIGS. 2a and 2b. This permits movement, also in a reciprocating manner, of the wafer 12 in the process chamber 40.

To effect mechanical scanning in the orthogonal, X-direction (that is, into and out of the plane of the paper in FIG. 2a and left to right in FIG. 2b), the support arm 52 is mounted within a support structure. The support structure comprises a pair of linear motors 60 that are spaced from the longitudinal axis of the support arm 52 above and below it as viewed in FIG. 2a. Preferably, the motors 60 are mounted around the longitudinal axis so as to cause the force to coincide with the centre of mass of the support structure. However, this is not essential and it will of course be understood that a single motor may instead be employed to reduce weight and/or cost.

The support structure also includes a slide 62 which is mounted in fixed relation to the sledge 58. Movement of the linear motors 60 along tracks (not shown in FIG. 2a or 2b) disposed from left to right in FIG. 2b causes the support arm 52 likewise to reciprocate from left to right as viewed in FIG. 2b. The support arm 52 reciprocates relative to the slide 62 upon a series of bearings.

With this arrangement, the wafer 12 is movable in two orthogonal directions (X and Y) relative to the axis of the ion beam (Z) such that the whole wafer 12 can be passed across the fixed direction ion beam 34.

FIG. 2a shows the sledge 58 in a vertical position such that the surface of the wafer 12 is perpendicular to the axis of the incident ion beam 34. However, it may be desirable to implant ions into the wafer 12 at an angle to the ion beam 34. For this reason, the rotor plate 56 is rotatable about an axis defined through its centre, relative to the fixed wall of the process chamber 40. In other words, the rotor plate 56 is able to rotate in the direction of the arrows R shown in FIG. 2a thereby causing the wafer 12 to rotate in the same sense.

Further details of the above arrangement can be found in our U.S. Pat. No. 6,956,223, the contents of which are incorporated herein in their entirety.

In a preferred arrangement, the chuck 36 is controlled to move according to a sequence of linear movements across the ion beam 34 in the X-coordinate direction, with each linear movement separated by a stepwise movement in the Y-coordinate direction. The resulting scan corresponds to a raster pattern. The reciprocating scanning action of the wafer 12 ensures that all parts of the wafer 12 are exposed to the ion beam 34.

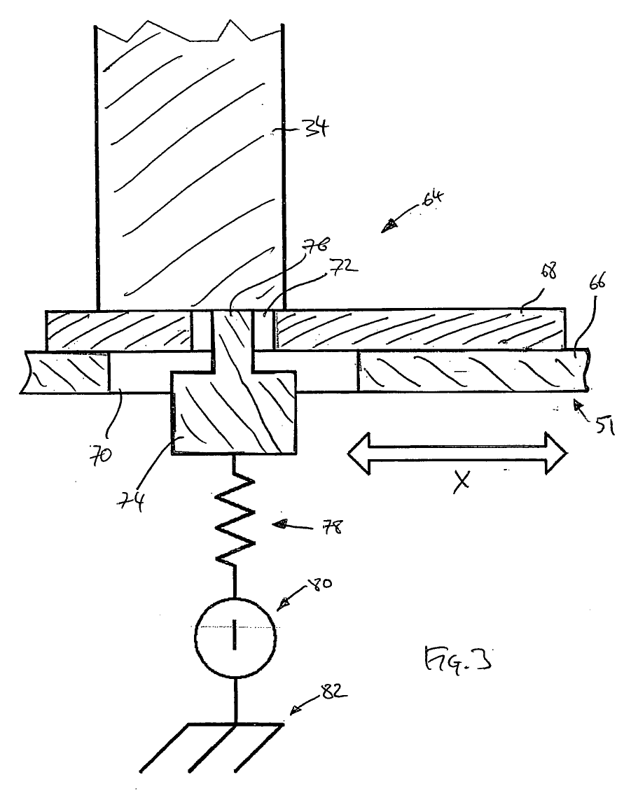

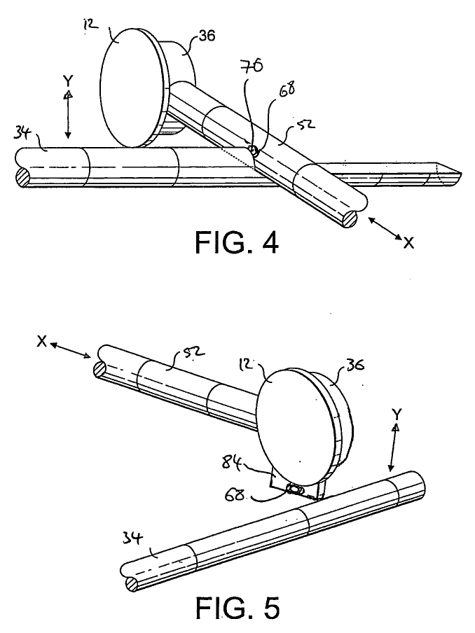

FIG. 3 provides a schematic representation of a device 64 for measuring the floating potential in and around an ion beam 34. The device 100 may be provided on the scanning arm assembly 51 at various locations, as will be described in further detail with reference to FIGS. 4 to 7.

The device 64 is mounted to a surface 66 of the scanning arm assembly 51 via an insulating plate 68. The surface 66 is at ground potential. Concentric apertures 70 and 72 are provided in the surface 66 and insulating plate 68 respectively. The insulating plate 68 is circular in cross-section and has a diameter of 30 mm. The diameter of the aperture 72 provided in the insulating plate 68 is 8 mm. The diameter of the aperture 70 provided on the surface 66 of the scanning arm assembly 51 is larger. A sensor 74 with a narrow tip 76 is housed within the scanning arm assembly 51 such that the sensor tip 76 terminates at the front face of the insulator plate 68 and to leave a void around the sensor 74. The sensor tip 76 has a diameter of 5 mm. The sensor 74, including tip 76, is preferably made from graphite or silicon.

The sensor 74 is electrically connected in series to a resistor 78, a current meter 80, and then to ground 82. The insulator plate 68 allows the space surrounding the sensor 74 to float to the potential of the ion beam 34. The sensor 74 receives charge from the ion beam 34, either net positive or negative, until the current saturates. The current flow may be measured by the current meter 80. When a measurement is taken, the scanning arm assembly 51 is moved such that device 74 occupies the desired position. Once the current has saturated, the value provided by the current meter 80 is used by the controller 50 to calculate the floating potential at that point. This potential is merely the product of the measured current and the resistance of the resistor 78 (this value is stored in an associated memory of the controller 50). In this embodiment, the resistance is chosen to be 10 MΩ as this is believed to be an optimum considering the net charge flow and the potential range of about 10 V.

As mentioned above, the diameter of the sensor tip 76 is 5 mm. This compares to a typical ion beam diameter of 30-100 mm that exerts a floating potential over a region in the order of 120-150 mm across. Hence, the sensor 74 effectively samples a point from within the ion beam 34. A profile of the floating potential over a cross-section through the ion beam 34 can be provided by moving the sensor 74 through the ion beam 34. As the sensor 74 is provided on the scanning arm assembly 51, the assembly 51 can be used to move the sensor 74. As explained above, the scanning arm assembly 51 is usually moved along X and Y axes to implement a raster scan. This same procedure may be used to obtain measurements from a two-dimensional array of positions within and adjacent to the ion beam 34. As it is the controller 50 that effects movement of the scanning arm assembly 51 via encoders, the controller 50 can determine both the sensor position and the measured floating potential at that position, and so provide a display of the potential profile of the ion beam 34.

The display could take any one of a number of forms and may show the raw data, filtered data or further data derived by interpolation for example (e.g. so as to show a contour plot). As will be appreciated, measurements may be taken at different positions within the ion beam 34 to produce any desired array of points, and need not be acquired following the raster scan suggested above. The number of points used may be determined as a balance between the resolution of the resulting profile and the time required to collect the measurements. For example, regularly-spaced arrays of 32×32 or 64×64 data points may be used.

The controller may also use the measurements of the floating potential of the ion beam to implement control changes. For example, if the measurements indicate a net positive charge, the controller 50 may increase the electron current from the plasma flood system 37. Conversely, an indication of a net negative charge may result in the controller 50 decreasing the electron current from the plasma flood system 37. Beam shaping may also be performed in response to the measured potentials, for example to increase uniformity across the ion beam 34 as well as reducing the absolute values of the potentials seen.

FIG. 4 shows the device 64 for measuring the floating potential of the ion beam 34 provided in the support arm 52 so as to face outwardly in the same direction as the wafer 12 when mounted on chuck 36. Thus, the insulator plate 68 is attached to the support arm 52, with the sensor 74 extending into the support arm 52. A profile of the ion beam 34 may be obtained by driving the scanning arm assembly 51 such that the sensor 74 provided on the support arm 52 travels through the ion beam 34. For this embodiment, the sensor tip 78 is brought to the plane of the wafer 12 by the thickness of the insulator plate 68.

An alternative arrangement is shown in FIG. 5 where the device 64 is provided in a tab 84 extending from the edge of the chuck 36. The insulator plate 68 is provided on the front face of the tab 84 such that the sensor 74 faces forwards in the same direction as the wafer 12. The tab 84 is positioned such that the sensor tip 78 is at the plane of the wafer 12. Measurements are taken by driving the sensor 74 in the tab 84 through the ion beam 34 using the scanning arm assembly 51.

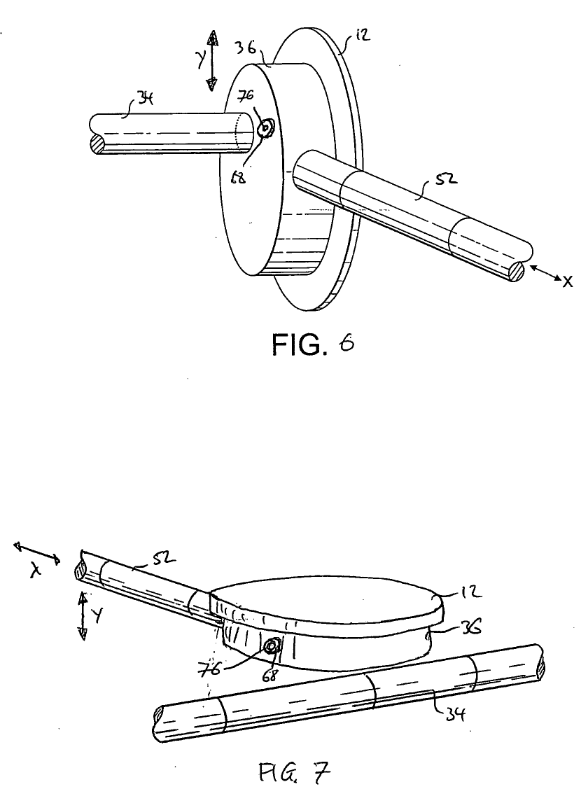

Yet another embodiment of the present invention is shown in FIG. 6 where the device 64 is provided in the back of the chuck 36 such that the sensor 74 faces in the opposite direction to wafer 12. The insulating plate 68 is mounted to the back of the chuck 36 at any suitable location. Measurements are taken by first rotating the support arm 52 so that the wafer 12 is turned away from the ion beam 34 and so that the back of the chuck 36 faces the ion beam 34. The scanning arm assembly 51 is then used to drive the sensor 74 through the ion beam 34. The device 64 may be positioned such that, when rotated to face the ion beam 34, the sensor tip 78 resides at the plane of the wafer 12 during implants.

A still further embodiment is shown in FIG. 7 where the device 64 is provided in the edge of the chuck 36 such that when the wafer 12 is held in the implant position, the sensor 74 faces downwards. Thus, the support arm 53 is rotated through 90° to make the sensor 74 face the ion beam 34 before measures are taken. The scanning arm assembly 51 is used, as before, to drive the sensor 74 through the ion beam 34.

As will be evident to the skilled person, changes may be made to the above embodiments without departing from the scope of the present invention as defined by the appended claims.

FIGS. 4 to 7 show the device 64 for measuring the floating potential of the ion beam 34 in a variety of positions on the scanning arm assembly 51. It will be clear that other positions may be used with success. As illustrated in FIGS. 4 to 7, the sensor 74 can be arranged to face in a variety of directions relative to the wafer 12, for example in the same direction, in the opposite direction or at 90° to the wafer 12. This may be achieved using different parts of the scanning arm assembly 51. Clearly, any angle may be adopted by placing the insulator plate 68 accordingly on the cylindrical support arm 52. Different directions may be achieved using the back and edge of the chuck 36. Similarly, the front, back and lower edge of the tab 84 of FIG. 5 may be used to align the sensor 74 as required.

While acquiring measurements, the controller 50 may be used to drive the scanning arm assembly 51 to whatever positions are desired and following whatever path is desired. Regularly spaced arrays of points is an obvious choice. The arrays may be rectangular or may be arranged to join concentric circles, bearing in mind the usual rotational symmetry of the ion beam 34. The data points need not be regularly spaced, for example the data points may be arranged more densely at the centre of the ion beam 34 where the ion beam flux is greatest.

As mentioned above, an array of devices 64 may be used rather than just a single device 64. In this case, the readings necessary to derive an array of floating potential measurements may be obtained in one sampling period, rather than having to move repeatedly the device 64 from one measuring position to the next. It will be straightforward for one skilled in the art to determine how such an array may be mounted to the scanning arm assembly 51, and how to manage the signals arriving from each device 64.

All embodiments described above relate to scanning arm assemblies 51 that effect mechanical scanning of the wafer 12. This is a preferred arrangement in that such scanning arm assemblies 51 provide greater flexibility in positioning the device 64. For example, the available rotation of the support arm 52 allows the device 64 to face in a different direction to that of the wafer 12. Nonetheless, it will be evident how the above embodiments are readily adaptable to an ion implanter 10 that scans an ion beam 34 relative to a wafer 12 that is held in a fixed position or to a hybrid ion implanter 10 that uses a mixture of ion beam movement and wafer movement. Also, it will be appreciated that the present invention may be used with batch processing implanters, for example those that use a spoked wheel, each spoke comprising a support arm and a wafer holder attached to the remote end of the support arm.

The actual form of the device 64 for measuring the floating potential of the ion beam 34 may be varied from that shown in FIG. 3. Several well-known arrangements are available, for example a non-contacting voltmeter that has an appropriately fast response. While more expensive, such a voltmeter should provide better accuracy than the arrangement of FIG. 3. WO02/23583 describes an alternative device 64.

1. An ion beam monitoring arrangement for an ion implanter, the ion beam monitoring arrangement comprising:
a substrate support comprising a support arm and, mounted thereto, a substrate holder for holding a substrate of contemplated size;
an actuator arranged to cause relative motion between the substrate holder and the ion beam; and
a device configured to measure the floating potential of an ion beam when incident thereon;
wherein the device is coupled to the substrate support so as to face outwardly in a position so as not to be obscured by a substrate of the contemplated size when held by the substrate holder.

2. The ion beam monitoring arrangement of claim 1, wherein the device is positioned so as to face in the same direction as a substrate when held by the substrate holder.

3. The ion beam monitoring arrangement of claim 1, wherein the device is positioned so as to face in the opposite direction as a substrate when held by the substrate holder.

4. The ion beam monitoring arrangement of claim 1, wherein the device is coupled to the support arm.

5. The ion beam monitoring arrangement of claim 4, wherein the device is mounted within the support arm so as to face outwardly through an aperture provided in the support arm.

6. The ion beam monitoring arrangement of claim 1, wherein the device is mounted to the substrate holder.

7. The ion beam monitoring arrangement of claim 6, wherein the device is mounted to a part of the substrate holder that extends beyond the extent of a substrate of the contemplated size when held by the substrate holder.

8. The ion beam monitoring arrangement of claim 7, wherein the device faces in the direction of a substrate when held by the substrate holder.

9. The ion beam monitoring arrangement of claim 6, wherein the device is mounted within the substrate holder so as to face outwardly through an aperture provided in the substrate holder.

10. The ion beam monitoring arrangement of claim 1, wherein the actuator is arranged to drive the support arm thereby causing the substrate holder to move through the ion beam.

11. The ion beam monitoring arrangement of claim 10, wherein the support arm is rotatable about its longitudinal axis.

12. The ion beam monitoring arrangement of claim 10, wherein the actuator has a part operable to drive the support arm along its length.

13. The ion beam monitoring arrangement of claim 10, wherein the actuator has a part operable to drive the support arm perpendicularly to its length.

14. The ion beam monitoring arrangement of claim 1, wherein the device is integral with the substrate support.

15. The ion beam monitoring arrangement of claim 1, wherein the device comprises a front, insulating plate with an aperture provided therein.

16. The ion beam monitoring arrangement of claim 15, wherein the device is attached to the substrate support using the insulating plate.

17. The ion beam monitoring arrangement of claim 15, wherein the device comprises a sensor positioned behind the aperture of the insulating plate.

18. The ion beam monitoring arrangement of claim 17, wherein the sensor is connected electrically to a resistor and a current meter.

19. The ion beam monitoring arrangement of claim 1, wherein the device is a non-contacting voltmeter.

20. The ion beam monitoring arrangement of claim 1, wherein the device is one of an array of like devices.

21. An ion implanter comprising the ion beam monitoring arrangement of claim 1.

22. A method of measuring the floating potential of an ion beam using the ion implanter of claim 21, the method comprising:
using the actuator to cause relative motion between the substrate support and the ion beam such that the device adopts a first measuring position in the ion beam; and
using the device to measure the floating potential at the first measuring position.

23. The method of claim 22, further comprising displaying the floating potential on a display.

24. The method of claim 22, further comprising using the actuator such that the device adopts a second measuring position in the ion beam, and using the device to measure the floating potential at the second measuring position.

25. The method of claim 22, further comprising using the actuator such that the device adopts an array of measuring positions in the ion beam, and using the device to measure the floating potential at each measuring position.

26. The method of claim 25, further comprising displaying the floating potentials on a display as a profile of the floating potential of the ion beam.

27. The method of claim 25, comprising using the actuator to scan the device through the ion beam according to a raster pattern.

28. The method of claim 22, comprising using the device to measure the floating potential while a substrate is held by the substrate holder.

29. The method of claim 22, comprising using the actuator to move the substrate support relative to a fixed ion beam.

30. A method of implanting a substrate using the ion implanter of claim 21, the method comprising:
generating an ion beam using an ion source of the ion implanter;
guiding the ion beam through the ion implanter towards the substrate holder using ion optics of the ion implanter;
using the actuator to cause relative movement between a substrate held by the substrate holder and the ion beam thereby to form a first scan line as the ion beam passes over the substrate;
repeating the above step of using the actuator so as to cause the ion beam to scan over the substrate repeatedly to form a series of scan lines; and,
between two successive steps of using the actuator to form scan lines across the substrate, using the actuator to cause relative movement such that the device adopts a first measuring position in the ion beam and using the device to measure the floating potential at the first measuring position.

31. The method of claim 30 further comprising, between the two successive steps, using the actuator such that the device adopts an array of measuring positions in the ion beam, and using the device to measure the floating potential at each measuring position.

32. The method of claim 30, comprising using the actuator to move the substrate support relative to a fixed ion beam.

33. A controller arranged to implement the method of claim 22.

34. A computer programmed to implement the method of claim 22.

35. A computer program that when loaded and executed on a computer, causes that computer to implement the method of claim 22.

36. A computer readable medium carrying thereon the computer program of claim 35.
